(19) United States
(12) Patent Application Publication
(10) Pub. No.: US 2006/0002092 A1
(43) Pub. Date: Jan. 5, 2006

(54) Board mounted heat sink using edge plating

(75) Inventor: David L. Stevens, Balch Springs, TX (US)

Correspondence Address: HITT GAINES P.C., P.O. BOX 832570, RICHARDSON, TX, 75083, US

(73) Assignee: Tyco Electronics Power Systems, Inc., A Nevada Corporation, Mesquite, TX (US)

(21) Appl. No.: 10/884,727

(22) Filed: Jul. 2, 2004

(51) Int. Cl. H05K 7/20

(52) U.S. Cl. 361/719

(57) ABSTRACT

The present invention provides a PWB having a heat sink connected to the internal circuits of the PWB that allows for heat dissipation from those internal circuits. In one aspect, the PWB includes at least two insulating layers that are coupled together and that have a conductive layer located therebetween. A conductive interconnect is located on an edge of or through the PWB and is thermally coupled to the conductive layer and a heat sink. The conductive layer forms a thermal conductive path from the conductive layer to the heat sink and thereby allows for heat to be dissipated from within an internal portion of the PWB.

### TECHNICAL FIELD OF THE INVENTION

The present invention is directed, in general, to a printed wiring board (PWB) having a heat sink mounted thereon, and more specifically, to a PWB having a heat sink connected to its internal circuits by use of a conductive interconnect.

### BACKGROUND OF THE INVENTION

It is well known that electronic and electrical components or devices mounted on a PWB generate considerable operating heat. In addition, however, internal circuits or traces in the PWB generate a considerable amount of heat within the internal portions of the PWB. Heat build-up within and on these PWBs has been exacerbated by increased device density, which results in more devices and internal interconnects, both of which generate more heat than ever before, and at the same time, makes less space available on the board for conventional heat sink devices. As is well known by those in the industry, unless this heat is properly dissipated, it can result in temperature related circuit or component failure. Therefore, it is highly desirable that as much of this heat as possible is removed.

The generally preferred method to effectuate heat dissipation is to use a metallic heat transfer device, such as a heat sink or heat plate, to transport heat from a component to the surrounding ambient air. Heat transfer devices can be made of any material with favorable heat transfer characteristics, such as copper or aluminum. In most cases, the heat transfer device and the related heat generating surface mounted components are placed in close proximity with one another and coupled with a thermal interface material in order to provide more efficient cooling of the component. This permits the heat sink to absorb component heat directly and transfer it to the surrounding ambient air by conduction or convection.

While, these types of heat sinks are able to dissipate heat from top surface devices, they are ineffective in removing heat generated by internal circuit traces. The reason that they are ineffective is that the heat has to travel a rather long and arduous distance to ultimately reach the heat sink. For example, a trace located in the internal portions of the PWB must conduct through several insulating layers before finally reaching the externally mounted device and the heat sink which is in contact with the mounted device. These insulating layers do not have a high thermal conductivity coefficient, and as a result, the heat cannot be dissipated rapidly enough to prevent an excessive build-up of heat within the PWB, given the amount of heat that is generated by the components and the internal circuits themselves.

Accordingly, what is needed is a heat sink that is capable of removing heat not only from the external components on the outer portions of the PWB, but is capable of efficiently removing heat from the internal circuits as well.

### SUMMARY OF THE INVENTION

To address the above-discussed deficiencies of the prior art, the present invention provides a PWB having a heat sink connected to the internal circuits of the PWB that allows for heat dissipation from those internal circuits. In one embodiment, the PWB includes at least two insulating layers that are coupled together and that have a conductive layer located therebetween. A conductive interconnect is thermally coupled to the conductive layer, and a heat sink is thermally coupled to the conductive interconnect.

In another embodiment, the present invention provides an electronic circuit module that includes a PWB that has heat generating components located thereon. The PWB has a plurality of insulating layers coupled together with a conductive layer located between each pair of the plurality of insulating layers. This embodiment further includes a conductive interconnect that is thermally coupled to the conductive layer, which is connected to ground. A heat sink is thermally coupled to the conductive interconnect.

In another embodiment, there is provided a method of manufacturing a PWB. The method includes providing at least two insulating layers coupled together that have a conductive layer located therebetween, forming a conductive interconnect that is thermally coupled to the conductive layer, and thermally coupling a heat sink to the conductive interconnect.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

For a more complete understanding of the present invention, reference is now made to the following detailed description taken in conjunction with the accompanying FIGUREs. It is emphasized that various features may not be drawn to scale. In fact, the dimensions of various features may be arbitrarily increased or reduced for clarity of discussion. Reference is now made to the following descriptions taken in conjunction with the accompanying drawings, in which:

FIG. 1 is an enlarged, partial sectional view of one embodiment where the heat sink is connected to the conductive layer by an edge plating interconnect;

FIG. 2 is an enlarged partial sectional view of another embodiment of the device illustrated in FIG. 1 wherein the edge plating interconnect is divided into multiple interconnects on the edge of the PWB;

FIG. 3 is an enlarged partial cross-sectional view of another embodiment wherein the conductive interconnect is a via formed through the PWB, and the heat sink is connected to the conductive layers by the via;

FIG. 4A is a perspective view of opposing sides of an electronic circuit module implementing a heat sink in accordance with the principles of the present invention.

FIG. 4B is an alternative embodiment of the electronic module circuit module of FIG. 4A showing interconnects that can be used to connect to another PWB board; and

FIG. 4C illustrates the electronic circuit module of FIG. 4B attached to another PWB board, which can function as a heat sink to dissipate internal heat within the electronic circuit module.

### DETAILED DESCRIPTION

The present invention recognizes the advantages associated with providing a heat sink that is connected to internal conductive layers of a PWB through a conductive interconnect. Because the heat sink is connected to the internal conductive layers, it provides a thermal path for heat that is generated by the internal circuits located between the insulative layers of the PWB. Thus, internal heat is more easily dissipated than conventional heat sink configurations.

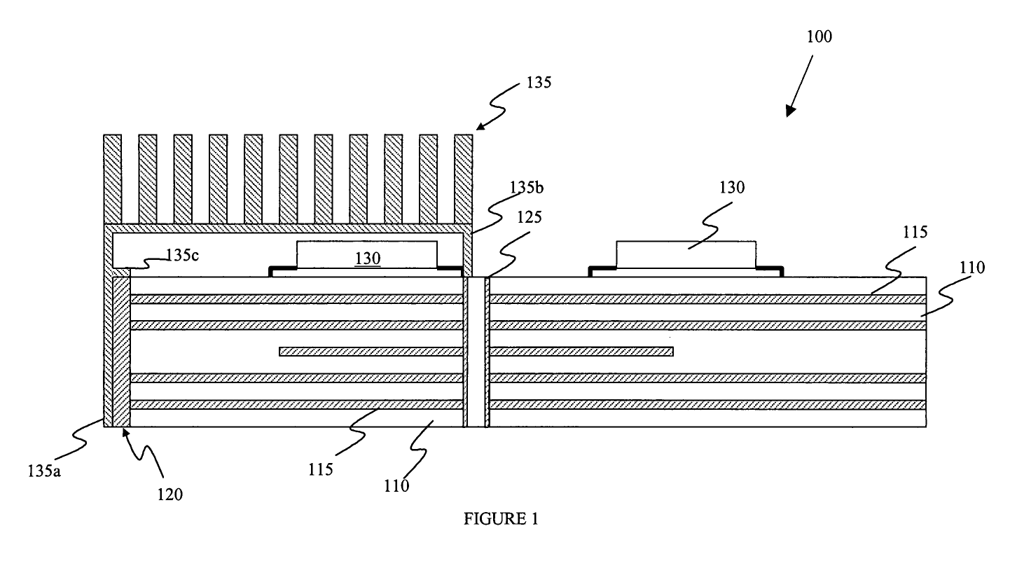

Turning initially to FIG. 1, there is illustrated an enlarged, partial sectional view of a PWB 100 showing multiple insulating layers 110 that have conductive layers 115 therebetween, only two of which, in each instance, have been designated for simplicity. The PWB 100 further includes a conductive interconnect 120, which, in this exemplary embodiment, is an edge plate interconnect and is discussed in more detail below. The conductive interconnect 120 may be formed on an edge of the PWB 100 and is connected to conductive layers 115. The conductive layers 115 extend to a via 125, which in one embodiment, is connected to ground. The conductive layers 115 are thermally conductive, and as such, provide a thermal path for heat generated within the interior portions of the PWB 100. Heat generating components 130 are located on a surface of the PWB 100, and they may be of any type of heat generating components typically found on a PWB. For example, they may be processors, capacitors, inductors, transformers, memory devices, switches or resistors.

A heat sink 135, which is also shown in this embodiment, is located over the PWB 100 and over the heat generating component 130. The heat sink 135 has a first end 135a that is in contact with the conductive layers 115 by way of the conductive interconnect 120 and a second end 135b that is in contact with the via 125, which in one embodiment, may be connected to ground. In one embodiment, the heat sink 135 may also include an edge 135c that laps over and contacts the PWB 100 as shown. Because the heat sink 135 is in contact with the conductive layers 135, the heat can conduct along the conductive layers 135 to the heat sink 135 and be dissipated, thereby allowing internal heat within the PWB 100 to be more efficiently removed from the PWB 100. Further, since the heat sink 135 can be placed in close proximity to the heat generating components 130, it is able to remove heat from the surface of the PWB 100, as well. The heat sink 135 may be coupled to the PWB 100 in a number of ways. For example, the first end 135a and the edge 135c may be soldered onto the PWB 100, or alternatively, they may form a spring clip that allows the heat sink 135 to be clipped onto the PWB 100. Other mechanical means known to those skilled in the art for attaching the heat sink 135 to the PWB 100 are within the scope of the present invention.

With an overview of one device having now been discussed, attention will now be turned to other embodiments illustrating different examples of the types of conductive interconnects that can be effectively used in conjunction with a heat sink to remove heat from internal portions of the PWB.

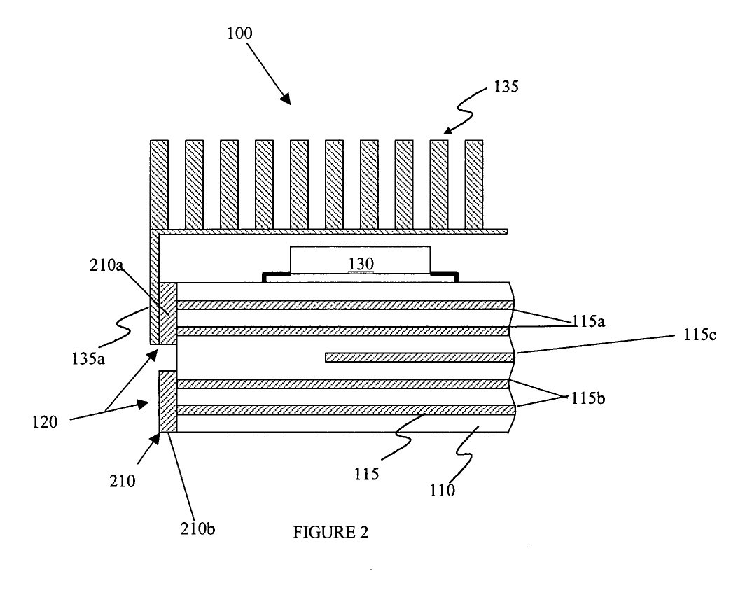

Turning now to FIG. 2 with continued reference to FIG. 1, there is illustrated an enlarged, partial sectional view of an edge of the PWB 100, as illustrated in FIG. 1. This figure illustrates one exemplary embodiment of the conductive interconnect 120 to which the heat sink 135 of FIG. 1 may be connected. In this embodiment, the conductive interconnect 120 is an edge plate interconnect 210. The edge plate interconnect 210 may be separated into multiple and electrically separate plates on a given edge of the PWB 200, as shown in FIG. 2, or it may be a single plate as illustrated in FIG. 1. In the embodiment where the edge plate interconnect 210 is separated into multiple plates 210a, 210b, the heat sink 135 may contact either one or both of the plates 210a, 210b. In the illustration, the first end 135a of the heat sink 135 contacts only plate 210a. In this embodiment, a group of conductive layers 115a, 115b, terminate at and contact the edge plate interconnect 210 of the PWB 100, while conductive layer 115c does not terminate at the interconnect 210, as shown.

Edge plate interconnects 210a, 210b respectively contact each of the groups of conductive layers 115a, 115b. In those embodiments where the edge plate interconnect 210 includes multiple plates and the heat sink 135 is connected to those plates, both of the conductive layers 115a, 115b may extend across the PWB 100 and connect to a ground (not shown) such that the heat sink 135 does not emit electromagnetic interferences and needlessly draw current from the active devices of the circuit. However, in another embodiment where the heat sink 135 contacts only conductive layers 115a, the conductive layers 115b may not necessarily terminate at a ground; this will be dictated by design.

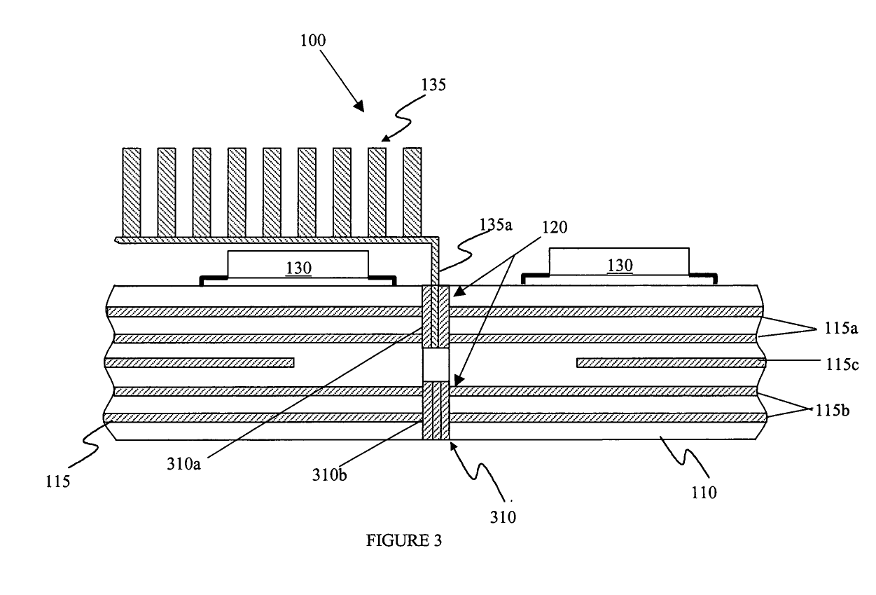

Turning now to FIG. 3, with continued reference to FIG. 1, there is illustrated another embodiment of the PWB 100 where the conductive interconnect 120, to which the heat sink 135 is connected, is a via 310 that is formed in or through the PWB 100. Similar to the edge plate interconnect of FIG. 2, the via 310 may have edge plating deposited on an interior surface of the via 310 such that a single plated interconnect is formed, such as the one illustrated in FIG. 1, or multiple, separate interconnects 310a, 310b, are formed. In the embodiment where the edge plate interconnect 310 is separated into multiple interconnects 310a, 310b, the heat sink 135 may contact either one or both of the interconnects 310a, 310b. In the illustrated embodiment, the first end 135a of the heat sink 135 contacts only plate 310a. In the embodiment that is illustrated, a group of conductive layers 115a, 115b, terminate at and contact the edge plate interconnect 310 of the PWB 100, while conductive layer 115c does not terminate at the interconnect 310, as shown.

Edge plate interconnects 310a, 310b respectively contact each of the groups of conductive layers 115a, 115b. In those embodiments where the edge plate interconnect 310 includes multiple, separate plates 310a, 310b, and the heat sink 135 is connected to those plates, conductive layers 115a, 115b may extend across the PWB 100 and connect to a ground (not shown) such that the heat sink 135 does not emit electromagnetic interferences and needlessly draw current from the active devices of the circuit. However, in another embodiment where the heat sink 135 contacts only conductive layers 115a, the conductive layers 115b may not terminate at a ground.

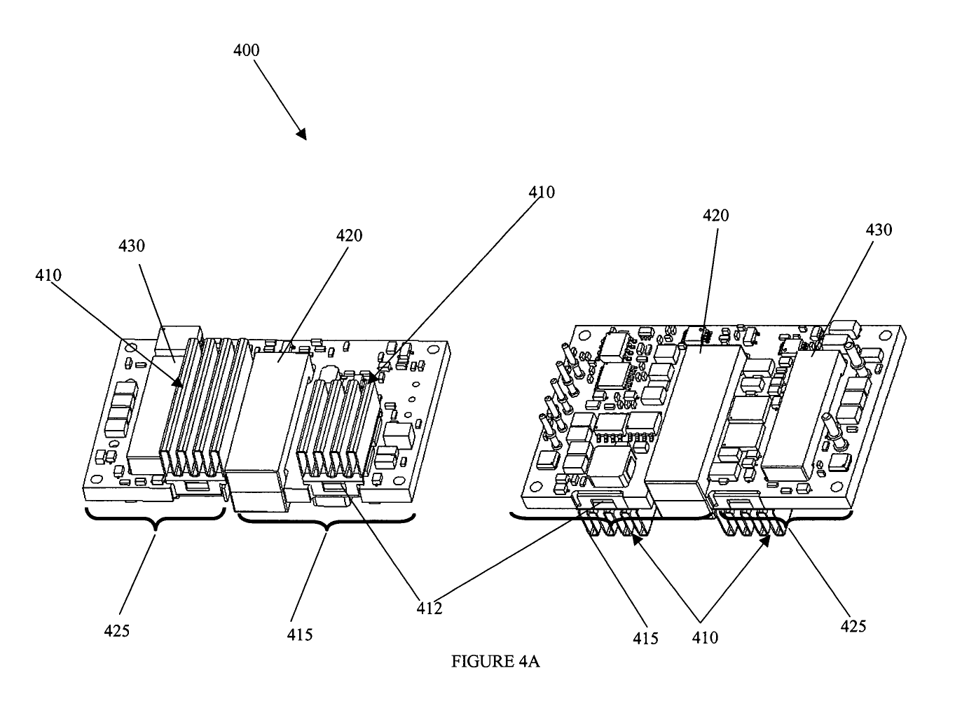

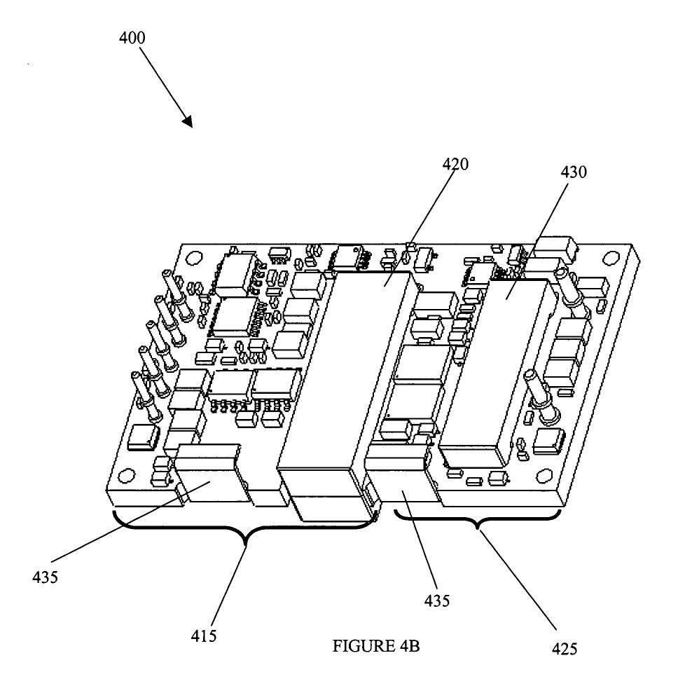

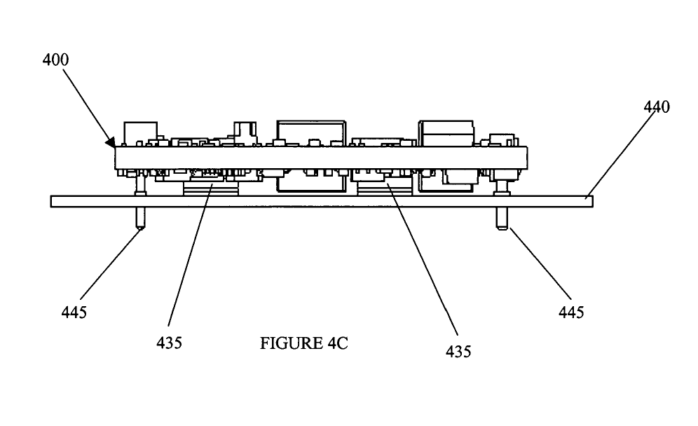

Turning now to FIG. 4A, there is illustrated a perspective view of opposing sides of an electronic circuit module 400 in accordance with the principles of the present invention. As shown, the electronic circuit module 400 includes a heat sink 410. In this particular embodiment, the heat sink 410 is connected to the internal circuits of the electronic circuit module 400 by an edge plate interconnect 412, as discussed above. While electronic design configurations my way, depending on the application, the electronic circuit module 400 may include a primary circuit 415, including a transformer 420 and a secondary circuit 425 that includes an output inductor 430 and other components as dictated by design, which are not specifically designated.

Turning now to FIGS. 4B and 4C, there is illustrated an alternative embodiment of the electronic circuit module 400 shown in FIG. 4A. This particular embodiment includes thermally conductive interconnects 435 that are coupled, such as by solder, to the edge plating interconnect, as discussed above. In the illustrated embodiment, the conductive interconnects 435 may be copper strips that extend beyond the edge of the electronic circuit module 400. By virtue of the conductive interconnects 435 being thermally coupled to the edge plating, the conductive interconnects 435, in turn, are thermally coupled to the internal conductive layer or traces of the electronic circuit module 400, as described above. Thus, the conductive interconnects 435 are capable of conducting heat from the internal portions of the electronic circuit module 400.

However, in place of the conductive interconnects 435 being connected to a heat sink, as in other embodiments discussed herein, these conductive interconnects 435 can be used to thermally couple the internal conductive layers or traces of the electronic circuit module 400 to another PWB board 440, such as a customer's board. The electronic circuit module 400 may also be electrically connected to the PWB 440 by way of conductive pins 445. Thus, the PWB board 440 can act as a heat sink for the electronic circuit module 400 by way of the conductive interconnects 435.

One who is skilled in the art, given the teachings discussed herein would understand how to construct the PWB, its interconnects, and connect the heat sink to those interconnects, including which materials to use. For example, the conductive layers may be copper trace patterns formed on the various layers of the PWB, and the conductive interconnects may comprise copper plated with a conductive solder. The conductive interconnect may be formed on an edge of the PWB as discussed above, or it may be formed on a routed slot formed in the interior of the PWB. Where the conductive interconnect is a via or some other type of opening, it may be formed by drilling a hole through the PWB.

Although the present invention has been described in detail, those skilled in the art should understand that they can make various changes, substitutions and alterations herein without departing from the spirit and scope of the invention in its broadest form.

What is claimed is:

1. A printed wiring board (PWB), comprising:
at least two insulating layers coupled together and having a conductive layer located therebetween;
a conductive interconnect thermally coupled to said conductive layer; and
a heat sink thermally coupled to said conductive interconnect.

2. The PWB as recited in claim 1 wherein said conductive interconnect is located on an edge of or through said PWB and in contact with said conductive layer and said heat sink is in contact with said conductive interconnect, said conductive layer formin a thermal conductive path to said heat sink for heat generated within an interior portion of said PWB.

3. The PWB as recited in claim 1 wherein said conductive interconnect is electrically connected to ground.

4. The PWB as recited in claim 3 further including a ground connect located on said PWB and said wherein heat sink has a first edge connected to said conductive interconnect and a second edge connected to said ground connect.

5. The PWB as recited in claim 1 wherein said conductive interconnect is an edge plate located on an edge of said PWB.

6. The PWB as recited in claim 1 wherein said heat sink is located over said PWB.

7. The PWB as recited in claim 6 further including a heat generating component located on said PWB and said heat sink is located over said heat generating component.

8. The PWB as recited in claim 1 wherein said conductive interconnect is a via formed through said PWB.

9. The PWB as recited in claim 1 wherein said heat sink is another PWB.

10. An electronic circuit module, comprising;
a printed wiring board (PWB)having heat generating components located thereon, said PWB having a plurality of insulating layers coupled together and having a conductive layer located between each pair of said plurality of insulating layers;
a conductive interconnect thermally coupled to said conductive layer, said conductive layer being connected to ground; and
a heat sink thermally coupled to said conductive interconnect.

11. The electronic module as recited in claim 10 wherein said conductive interconnect is located on an edge of or through said PWB and in contact with said conductive layer and said heat sink is in contact with said conductive interconnect, said conductive layer formin a thermal conductive path to said heat sink for heat generated within an interior portion of said PWB.

12. The electronic module as recited in claim 10 further including a ground connect located on said PWB and said heat sink has a first edge connected to said conductive interconnect and a second edge connected to said ground connect.

13. The electronic module as recited in claim 10 wherein said conductive interconnect is an edge plate located on an edge of said PWB.

14. The electronic module as recited in claim 10 further including a heat generating component located on said PWB and said heat sink is located over said heat generating component.

15. The electronic module as recited in claim 10 wherein said conductive interconnect is a via formed through said PWB.

16. The electronic module as recited in claim 10 wherein said PWB is configured as a power module.

17. The electronic module as recited in claim 10 wherein said conductive layer comprises copper.

18. The electronic module as recited in claim 10 wherein said heat sink is another PWB.

19. A method of manufacturing a printed wiring board (PWB), comprising:
providing at least two insulating layers coupled together and having a conductive layer located therebetween;
forming a conductive interconnect thermally coupled to said conductive layer; and
thermally coupling a heat sink to said conductive interconnect.

20. The method as recited in claim 19 wherein said conductive interconnect is located on an edge or through said PWB and in contact with said conductive layer and thermally coupling includes connecting said heat sink to said conductive interconnect wherein said conductive layer forms a thermal conductive path to said heat sink for heat generated within an interior portion of said PWB.

21. The method as recited in claim 19 wherein forming said conductive interconnect includes connecting said conductive interconnect to ground.

22. The method as recited in claim 19 further including forming a ground connect on said PWB and connecting a first edged of said heat to said conductive interconnect and connecting a second edge of said heat sink to said ground connect.

23. The method as recited in claim 19 wherein forming said conductive interconnect includes forming an edge plate interconnect on an edge of said PWB.

24. The method as recited in claim 19 wherein forming said conductive interconnect includes forming a via through said PWB.

25. The method as recited in claim 19 wherein thermally coupling said heat sink includes positioning said heat sink over a heat generating component located on said PWB.

26. The method as recited in claim 19 wherein thermally coupling a heat sink includes coupling said PWB to another PWB.
